(19) United States
(12) Patent Application Publication
(10) Pub. No.: US 2007/0048961 A1
(43) Pub. Date: Mar. 1, 2007

(54) SEMICONDUCTOR DEVICE AND FABRICATING METHOD THEREOF

(76) Inventors: Ko-Hsing Chang, Hsinchu (TW); Wu-Tsung Chung, Miaoli County (TW); Tsung-Yu Lee, Miaoli County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 11/306,897

(22) Filed: Jan. 16, 2006

(30) Foreign Application Priority Data
Aug. 30, 2005 (TW) 94129616

(51) Int. Cl. H01L 21/20

(52) U.S. Cl. 438/386

(57) ABSTRACT

A semiconductor device and fabricating method thereof are provided. In the fabricating method, two trenches are formed in the substrate and, then the first dielectric layers is formed on the sidewalls of the trenches and a source/drain layer is formed in each trench. A second dielectric layer is formed on the substrate and the source/drain layer. Finally, a gate structure is formed on the second dielectric layer. The source/drain layers and the first dielectric layers are placed in trenches; therefore, device dimension can be reduced.

### CROSS-REFERENCE TO RELATED APPLICATION

This application claims the priority benefit of Taiwan application serial no. 94129616, filed on Aug. 30, 2005. All disclosure of the Taiwan application is incorporated herein by reference.

### BACKGROUND OF THE INVENTION

1. Field of Invention

The present invention relates to a semiconductor device and the fabricating method thereof, and more particularly, to a high voltage device and the fabricating method thereof.

2. Description of Related Art

Nowadays, the devices are getting smaller and smaller with the length of channels shortened to increase the operation speed of transistors. However, the problems caused by the shortened channels increase significantly. With reference to the formula of “electric field=voltage/length”, an increased in the speed of the electric field can increase the electron power in the channel and possibility of electrical breakdown, if supply of the voltage unchanged and the channel's length of the transistor reduced. In addition, along with the rise of the electron power in the channel, the intensity of the electric field and possibility of the electrical breakdown increase.

The conventional high voltage devices generally increase the space between source/drain by forming an isolation layer and gate to decrease the transverse electric field in the channel or reduce hot electron effect by performing lightly doping in the drift region under the isolation layer and the grade region under the source/drain region to increase the interface breakdown voltage of the source/drain region, and further ensure the high voltage device work properly under high voltage.

FIG. 1 is a diagram illustrating a conventional high voltage device. Referring to FIG. 1, the high voltage device is formed by a substrate 10, an n-type heavily doped region 12, an n-type lightly doped region 14, a p-type doped region 16, a gate dielectric layer 18, a gate structure 20, and a field oxide layer 22. The n-type heavily doped region 12 is disposed in the substrate 10 and is a source/drain region. The n-type lightly doped region 14 is also disposed in the substrate 10 and is adjacent to the n-type heavily doped region 12 and the p-type doped region 16. The p-type doped region 16 is disposed in the substrate 10 and adjacent to two n-type lightly doped region 14s. The gate dielectric layer 18 covers part of the substrate 10 and the whole p-type doped region 16. The field oxide layer 22 covers part of the substrate 10, which is uncovered by the gate dielectric layer 18. The gate structure 20 covers the gate dielectric layer 18 and part of the field oxide layer 22. The n-type lightly doped region 14 and the field oxide layer 22 is used for increasing the interface breakdown voltage of the source/drain. However, in the aforementioned high voltage device, the disposition of the field oxide layer 22 does not allow the size reduction of the high voltage device. Accordingly, the requirements for improving the integration of the semiconductor device can not be satisfied.

Additionally, to increase the breakdown voltage of a high voltage device, the doping density of the drift region is generally decreased. However, the current drive performance of the device is decrease at the same time. Meanwhile, in the application of high voltage devices, the latch up effect has to be considered. Relaxing the layout rule to improve the latch up effect will result in increment in the device's surface area.

### SUMMARY OF THE INVENTION

Accordingly, the present invention is directed to provide a semiconductor device by isolating the source/drain region with an oxide layer to increase the breakdown voltage and the current drive performance, and meet the requirement of high integration thereof.

According to another aspect of the present invention, a fabricating method for fabricating the aforementioned semiconductor device is provided for the operation under high voltage in which the process is simple and can expand the application range of integrated circuits on the wafers.

According to the present invention, a fabricating method for a semiconductor device is provided. First, a substrate having two trenches is provided. A first dielectric layer is formed on the sidewalls of each trench. Then, two source/drain layers are formed in each trench, and a second dielectric layer is formed on the substrate and the source/drain layers. Finally a gate structure is formed on the second dielectric layer between the source/drain layers.

According to the embodiment of aforementioned fabricating method for a semiconductor device of the present invention, the step of forming the source/drain layer in each trench includes: forming a first doped polysilicon layer to fill the two trenches on the substrate; removing part of the first doped polysilicon layer to make the surface of the first doped polysilicon layer lower than the surface of the substrate; removing part of the first dielectric layer on the sidewalls of the substrate between the two trenches and forming a second doped polysilicon layer to fill the trenches on the substrate.

According to the embodiment of aforementioned fabricating method for a semiconductor device of the present invention, the step of removing part of the first dielectric layer on the sidewalls of the substrate between the two trenches includes: forming a patterned photoresist layer for exposing at least the substrate between the two trenches and the sidewalls of the two trenches on the substrate and, removing part of the first dielectric layer uncovered by the patterned photoresist layer.

According to the embodiment of aforementioned fabricating method for a semiconductor device of the present invention, after the step of removing part of the first dielectric layer on the sidewalls of the substrate between the two trenches, a lightly doped region is further formed on the exposed part of the substrate on the sidewalls of the two trenches. And the method for forming the lightly doped region is tilt angle ion implantation.

According to the embodiment of aforementioned fabricating method for a semiconductor device of the present invention, the process for forming the second doped polysilicon layer is chemical vapor deposition.

According to the embodiment of aforementioned fabricating method for a semiconductor device of the present invention, the method for forming two trenches in the substrate includes steps of forming a patterned mask layer, which has two openings exposing the substrate and is removed before the step of forming the second dielectric layer on the substrate, and removing part of the substrate exposed by the two openings removed.

According to the embodiment of aforementioned fabricating method for a semiconductor device of the present invention, the dopant of the first doped polysilicon layer and the second doped polysilicon layer is n-type dopant or p-type dopant.

According to the embodiment of aforementioned fabricating method for a semiconductor device of the present invention, the aforementioned semiconductor device is high voltage device.

According to another aspect of the present invention, a semiconductor device including a substrate, an isolation dielectric layer, a source/drain layer, a gate structure, and a gate dielectric layer is provided. The substrate has two trenches. The isolation dielectric layer is disposed on the sidewalls of the two trenches. The two source/drain layers are disposed in the two trenches. The gate structure is disposed on the substrate between the two source/drain layers. The gate dielectric layer is disposed between the gate structure and the substrate.

According to the embodiment of aforementioned semiconductor device of the present invention, two lightly doped regions are further included. The two lightly doped regions are disposed respectively in the part of the substrate between the two source/drain layers and adjacent to the two source/drain layers directly.

According to the embodiment of aforementioned semiconductor device of the present invention, the two source/drain layers protrude from the surface of the substrate.

According to the embodiment of aforementioned semiconductor device of the present invention, the gate dielectric layer covers the two source/drain layers and the material of the gate dielectric layer is silicon oxide.

According to the embodiment of aforementioned semiconductor device of the present invention, a part of the gate structure spans over the two source/drain layers and the material of the gate structure is doped polysilicon.

According to the embodiment of aforementioned semiconductor device of the present invention, the semiconductor device is high voltage device.

According to the embodiment of aforementioned semiconductor device of the present invention, the material of the two source/drain layers is doped polysilicon.

It is noticeable that the source/drain layers and the isolation dielectric layer, according to one aspect of the present invention, are disposed in the trenches; therefore, the breakdown voltage of the source/drain is determined by the thickness of the isolation dielectric layer. Compared to the conventional technology, since the semiconductor device in the present invention does not need to reduce the dopant thickness of the drift region, the breakdown voltage can be increased. Moreover, since there is no field oxide layer disposed, the size of the semiconductor device is reduced considerably, and the integration of the semiconductor device on chips is further increased. In addition, the disposition of the isolation dielectric layer can avoid latch up effect efficiently.

In order to make the aforementioned and other objects, features and advantages of the present invention comprehensible, a preferred embodiment accompanied with figures is described in detail below.

It is to be understood that both the foregoing general description and the following detailed description are exemplary, and are intended to provide further explanation of the invention as claimed.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is a diagram illustrating a conventional high voltage device.

FIG. 2A to 2E are profile views illustrating the fabrication flow of a semiconductor device according to an exemplary embodiment of the present invention.

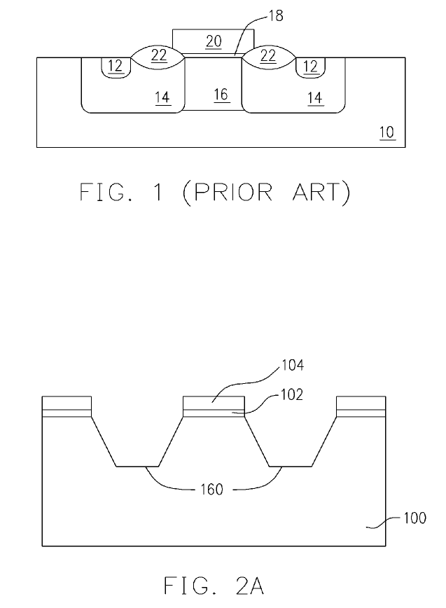

### DESCRIPTION OF EMBODIMENTS

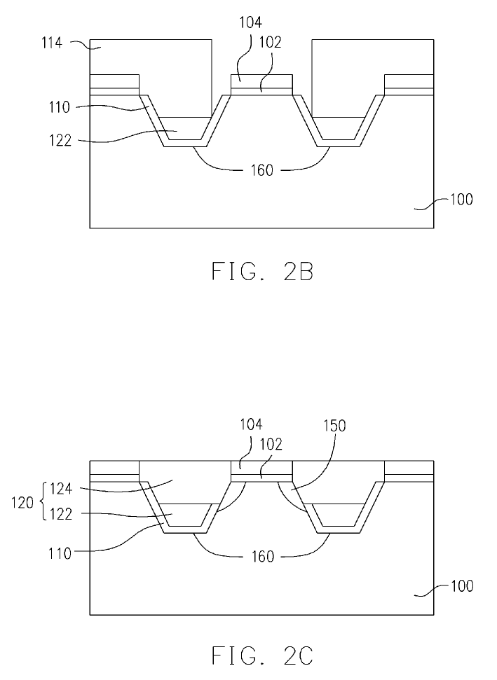

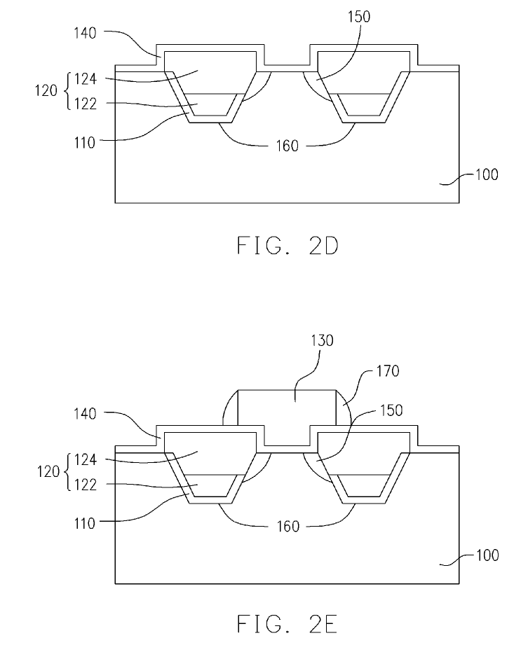

The formation method of the semiconductor device in the present invention will be explained below. Referring to FIG. 2A, a substrate 100 is provided and, then a patterned pad oxide layer 102 having two openings and a mask layer 104 are formed on the substrate 100. The material of the pad oxide layer 102 is silicon oxide, and the material of the mask layer 104 is silicon nitride. The formation method of the pad oxide layer 102 and the mask layer 104 includes steps of forming a layer of silicon oxide by thermal oxidation first, and forming a layer of silicon nitride by chemical vapor deposition, and then patterning the silicon nitride layer and the silicon oxide layer. The method of patterning the silicon nitride layer and the silicon oxide layer is photolithography etch process, for example. The part of the substrate 100 exposed by the two openings is removed with method like dry etching by using the mask layer 104 as mask to form two trenches 160 in the substrate 100. Referring to FIG. 2B, in the following step, a dielectric layer 110 is formed on the sidewall of each trench 160. The formation method of the dielectric layer 110 is thermal oxidation, and the material of the dielectric layers is silicon oxide. Next, a doped polysilicon material is formed for filling the trenches 160 on the substrate 100 and then, part of the doped polysilicon material is removed to make the surface of the doped polysilicon material lower than the surface of the substrate 100 to form the doped polysilicon layer 122. The methods of removing part of the doped polysilicon material are chemical mechanical polishing (CMP) and etching back method. Moreover, the dopant of the doped polysilicon layer 122 is an n-type dopant or p-type dopant. If the substrate 100 is an n-type substrate, the dopant of the doped polysilicon layer 122 is a p-type dopant. Otherwise if the substrate 100 is a p-type substrate, the dopant of the doped polysilicon layer 122 is an n-type dopant. In the following step, a patterned photoresist layer 114 is formed on the substrate 100. The patterned photoresist layer 114 exposes at least part of the area between the two trenches 160, the pad oxide layer 102 and the mask layer 104 between the two trenches 160, and part of the sidewalls of the two trenches 160.

Referring to FIG. 2C, part of the dielectric layer 110 uncovered by the patterned photoresist layer is removed to expose a part of the substrate 100 on the sidewalls of the trenches 160, wherein the method of removing part of the dielectric layer 110 is plasma dry etch with CXFY as reactant. Next, a lightly doped region 150 on the exposed part of substrate 100 of the two trenches 160 is removed, wherein the method of forming the lightly doped region 150 is tilt angle ion implantation. In the next step, the doped polysilicon layer 124, which fills up the two trenches 160 and is adjacent to the light doped region 150 through the exposed surface of the substrate 100, is formed on the substrate. Wherein the formation method of the doped polysilicon layer 124 is depositing doped polysilicon material (not shown herein) by chemical vapor deposition to cover the substrate 100, and performing chemical mechanical polishing with the mask layer 104 as polish stop layer. Moreover, the dopant of the doped polysilicon layer 124 is an n-type dopant or p-type dopant. The dopant of the doped polysilicon layer 124 and the dopant of the doped polysilicon layer 122 are both n-type dopants or are both p-type dopants. In the trenches 160, the combination of the doped polysilicon layer 124 and the doped polysilicon layer 122 is a source/drain layer of the semiconductor device described above, which is referred as reference number 120 herein.

Referring to FIG. 2D, in the follow step, the mask layer 104 and the pad oxide layer 102 are removed and then, a dielectric layer 140 is formed on the substrate 100 and the source/drain layer 120 in which the formation method thereof is chemical vapor deposition. The dielectric layer 140 is used as gate dielectric layer and the material thereof is silicon oxide.

Referring to FIG. 2E, a gate structure 130 is formed on the dielectric layer 140 between the source/drain layer 120. The gate structure 130 is formed by forming a layer of doped polysilicon material of chemical vapor deposition, and then patterning the doped polysilicon material layer. In addition, a part of the gate structure 130 is spanning over the source/drain layer 120. Then, spacers 170 are formed on the sidewalls of the gate structure 130. The material of the spacers 170 is silicon nitride. The formation method of the spacer 170 is includes forming a layer of insulating material layer and, then removing part of the insulating material layer by performing anisotropic etching process. The following process of the semiconductor device is well-known to those skilled in the art and will not be provided in details herein.

In the next step, the structure of a semiconductor device in an embodiment of the present invention will be explained with reference to FIG. 2E. Referring to FIG. 2E, the semiconductor device in the present invention includes a substrate 100, an isolation dielectric layer 110, a source/drain layer 120, a gate structure 130, a gate dielectric layer 140, a lightly doped region 150, and a spacer 170.

The material of the substrate 100 includes doped n-type or p-type silicon wafer in which two trenches 160 are disposed in the substrate 100.

In addition, the isolation dielectric layer 110 is located on the sidewalls of the trenches 160, but exposes a part of the substrate 100, and the material of the isolation dielectric layer 110 is silicon oxide.

Moreover, the lightly doped region 150 is located in the substrate 100 and adjacent to other structures through the exposed surface of the substrate 100 in the trenches 160. The disposition of the lightly doped region 150 is to prevent the short channel effect in the semiconductor device. However, the present invention is not subject to whether to dispose the lightly doped region 150 nor to expose part of the substrate 100 in the trenches 160.

On the other hand, the source/drain layer 120 is formed by the doped polysilicon layer 122 and the doped polysilicon layer 124, wherein the doped polysilicon layer 122 is located in the trenches 160. The doped polysilicon layer 124, adjacent to the lightly doped region 150, is also located in the trenches 160 and covers the doped polysilicon layer 122. Moreover, the doped polysilicon layer 124 protrudes from the surface of the substrate 100.

In addition, the gate structure 130 is disposed on the substrate 100 between the source/drain layer 120 to make a part of the gate structure 130 span over the source/drain 120. Moreover, the material of the gate structure 130 is doped polysilicon. Furthermore, a spacer 170 is disposed on the sidewalls of the gate structure 130 wherein the material of the spacer is silicon nitride.

Furthermore, the gate dielectric layer 140 is located between the gate structure 130 and the substrate 100. In addition, the gate dielectric layer 140 covers the source/drain layer 120, wherein the material of the gate dielectric layer is silicon oxide.

In an exemplary embodiment, the aforementioned semiconductor device is high voltage device.

It is noticeable that according to the present invention, the source/drain layers and the isolation dielectric layer are disposed in the trenches; therefore, the breakdown voltage of the source/drain is determined by the thickness of the isolation dielectric layer. Since the semiconductor device in the present invention does not require to reduce the dopant thickness of the drift region, the breakdown voltage can be increased. Moreover, no field oxide layer is disposed, the size of the semiconductor device is reduced considerably with the integration of the semiconductor device on chips further increased. In addition, the disposition of the isolation dielectric layer may avoid latch up effect efficiently.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A fabricating method for a semiconductor device, comprising:
providing a substrate;
forming two trenches in the substrate;
forming a first dielectric layer on the sidewalls of each of the two trenches respectively;
forming a source/drain layer in each of the two trenches respectively;
forming a second dielectric layer on the substrate and the two source/drain layers; and
forming a gate structure on the second dielectric layer between the two source/drain layers.

2. The method of claim 1, wherein the step of forming the source/drain layer in each trench comprises:
forming a first doped polysilicon layer to fill up the two trenches;
removing part of the first doped polysilicon layer to make the surface of the first doped polysilicon layer lower than the surface of the substrate;
removing part of the first dielectric layer on the sidewalls of the substrate between the two trenches; and
forming a second doped polysilicon layer on the substrate to fill up the two trenches.

3. The method of claim 2, wherein the step of removing part of the first dielectric layer on the sidewalls of the substrate between the two trenches comprises:
forming a patterned photoresist layer on the substrate, which at least exposes the substrate between the two trenches and a sidewall of the two trenches; and
removing part of the first dielectric layer uncovered by the patterned photoresist layer.

4. The method of claim 2, after the step of removing part of the first dielectric layer on the sidewalls of the substrate between the two trenches, further comprising:
forming a lightly doped region on the exposed part of the substrate on the sidewalls of the two trenches.

5. The method of claim 4, wherein the step for forming the lightly doped region on the exposed part of the substrate on the sidewalls of the two trenches comprises performing tilt angle ion implantation.

6. The method of claim 2, wherein the step for forming the second doped polysilicon comprises performing chemical vapor deposition.

7. The method of claim 2, wherein the step for forming the two trenches in the substrate comprises:
forming a patterned mask layer, which has two openings exposing the substrate and is removed before forming the second dielectric layer on the substrate; and
removing part of the substrate exposed by the two openings.

8. The method of claim 1, wherein the dopant of the first doped polysilicon layer and the second doped polysilicon layer is n-type dopant or p-type dopant.

9. The method of claim 1, wherein the semiconductor device is high voltage device.

10. A semiconductor device, comprising:
a substrate having two trenches;
an isolation dielectric layer disposed on the sidewalls of the two trenches;
two source/drain layers disposed in the two trenches;
a gate structure disposed on the substrate between the two source/drain layers; and
a gate dielectric layer disposed between the gate structure and the substrate.

11. The semiconductor device of claim 10 further comprising two lightly doped regions disposed in part of the substrate between the two source/drain layers respectively and adjacent to the two source/drain layers directly.

12. The semiconductor device of claim 10, wherein the two source/drain layers further protrude from the surface of the substrate.

13. The semiconductor device of claim 10, wherein the gate dielectric layer further covers the two source/drain layers.

14. The semiconductor device of claim 10, wherein a part of the gate structure spans over the two source/drain layers.

15. The semiconductor device of claim 10, wherein the material of the gate structure comprises doped polysilicon.

16. The semiconductor device of claim 10, wherein the semiconductor device is high voltage device.

17. The semiconductor device of claim 10, wherein the material of the isolation dielectric layer comprises silicon oxide.

18. The semiconductor device of claim 10, wherein the material of the gate dielectric layer comprises silicon oxide.

19. The semiconductor device of claim 10, wherein the material of the two source/drain layers comprises doped polysilicon.
